(19) United States
(12) Patent Application Publication
(10) Pub. No.: US 2026/0129989 A1
(43) Pub. Date: May 7, 2026

(54) COLLOIDAL QUANTUM DOT BASED IMAGE SENSOR

(71) Applicant: Attollo Engineering, LLC, Camarillo, CA (US)

(72) Inventor: Jet Meitzner, Camarillo, CA (US)

(21) Appl. No.: 18/936,466

(22) Filed: Nov. 4, 2024

(51) Int. Cl. H01L 27/146

(52) U.S. Cl. CPC H10F 39/8053; H10F 39/8023; H10F 39/803; H10F 39/8067

(57) ABSTRACT

A colloidal quantum dot (CQD) based image sensor. The CQD based image sensor includes a top contact layer, a light absorption layer, a readout integrated circuit (ROIC), and a pixel electrode. The quantum dot film includes colloidal quantum dots. The pixel electrode is positioned between the quantum dot film and the ROIC.

### TECHNICAL FIELD

The subject matter disclosed herein relates to photodetectors and, in particular, to colloidal quantum dot (CQD) based image sensors.

### BACKGROUND

Colloidal quantum dot (CQD) based image sensors (e.g., photodetectors) utilize a quantum dot film in the light absorption layer. The exciton absorption wavelength of the CQD layer is tunable due to the quantum confinement effect. To maintain the desired optical properties of the CQD, the quantum dots have a degree of physical and electronic isolation after deposition into the film layer of the photodetector device. However, the electronic isolation between quantum dots can result in low charge carrier mobilities, typically <0.1 cm2/V/s, which translates to lower drift velocity, higher probability of recombination, and lower quantum efficiency (QE). Light absorption, and therefore QE, can be enhanced by increasing CQD film thickness, however issues with film stress and adhesion limit this approach. Therefore, there exists a need to improve QE of CQD based image sensors. Further, CQD based image sensors can suffer from pixel saturation when incident light is too intense. Therefore, there exists a need for an improved dynamic range for quantum dot pixels within an array.

### SUMMARY

According to one aspect, a colloidal quantum dot (CQD) based image sensor. The CQD based image sensor includes a top contact layer, a light absorption layer, a readout integrated circuit (ROIC), and a pixel electrode. The quantum dot film includes colloidal quantum dots. The pixel electrode is positioned between the quantum dot film and the ROIC. The pixel electrode includes a base portion having a planar surface and a pillar extending from the planar surface toward the top contact layer.

According to another aspect, a colloidal quantum dot (CQD) based image sensor system. The CQD based image sensor system includes a top contact layer, a light absorption layer, a ROIC, a first plurality of pixel electrodes, and a second plurality of pixel electrodes. The light absorption layer includes a quantum dot film. The first plurality of pixel electrodes have a first height positioned between the top of the quantum dot film and the ROIC. The second plurality of pixel electrodes have a second height positioned between the top of the quantum dot film and the ROIC. The second height is greater than the first height. The first plurality of pixel electrodes and the second plurality of pixel electrodes collect charge carriers from the light absorption layer and are coupled to the ROIC.

According to another aspect, a colloidal quantum dot (CQD) based image sensor. The CQD based image sensor includes a top contact layer, a light absorption layer, a ROIC, and a pixel electrode positioned between the top of the quantum dot film and the ROIC on a planar surface. The pixel electrode includes a pyramidal structure.

### BRIEF DESCRIPTION OF THE DRAWINGS

FIG. 1A is a cross sectional diagrammatic view of a colloidal quantum dot (CQD) based image sensor, according to some embodiments.

FIG. 1B is a cross sectional diagrammatic view of a CQD based image sensor, according to some embodiments.

FIG. 2A is a cross sectional diagrammatic view of a CQD based image sensor with a plurality of top contact pillars, according to some embodiments.

FIG. 2B is a cross sectional diagrammatic view of a CQD based image sensor with a plurality of pixel electrode pillars, according to some embodiments.

FIG. 2C is a top view of a pixel electrode with a single electrode pillar, according to some embodiments.

FIG. 2D is a top view of a pixel electrode with a plurality of electrode pillars, according to some embodiments.

FIG. 2E is a top view of a pixel electrode with a plurality of electrode pillars, according to some embodiments.

FIG. 3A is a cross sectional diagrammatic view of a CQD based image sensor with a first plurality of pixel electrodes and a second plurality of pixel electrodes having a different height from the first plurality of pixel electrodes, according to some embodiments.

FIG. 3B is a top diagrammatic view of a sample region of pixel electrodes of a CQD based image sensor including a first plurality of pixel electrodes and a second plurality of pixel electrodes, according to some embodiments.

FIG. 4 is a flow chart of a method of improving dynamic range of pixels of a CQD based image sensor, according to some embodiments.

FIG. 5A is a cross sectional diagrammatic view of a CQD based image sensor with a plurality of pyramidal pixel electrodes, according to some embodiments.

FIG. 5B is a cross sectional diagrammatic view of a CQD based image sensor with a plurality of inverted pyramidal pixel electrodes, according to some embodiments.

### DETAILED DESCRIPTION

The present disclosure describes devices, systems, and methods for improving quantum efficiency (QE) and/or dynamic pixel saturation range of colloidal quantum dot (CQD) based image sensors. The CQD based image sensor includes a top contact layer, a plurality of pixel electrodes in communication with a readout integrated circuit (ROIC), and a quantum dot film layer (i.e., the light absorption layer) including colloidal quantum dots. There is a trade-off when increasing the thickness of the quantum dot film layer: as thickness increases, QE first increases due to more light absorption, but past an influx thickness, the QE decreases due to increasing recombination of photogenerated charges before the photogenerated charges reach the pixel electrodes to be read out by the ROIC of the photodetector device.

According to some aspects of the present disclosure, to improve QE, the plurality of pixel electrodes (e.g., bottom-contacts) include a pillar extending into the quantum dot film layer to reduce the transit distance to collect charge carriers (i.e., holes (h+) or electrons (e−)). Reducing a transit distance of the charge carriers improves QE, as the low mobility charge carriers have less distance to travel through the quantum dot film layer before collection. According to some aspects of the present disclosure, to improve QE, at least one of the plurality of pixel electrodes includes a pyramidal structure configured to reflect an incident photon within the quantum dot film layer. The reflection of a photon by the pyramidal structure enhances QE of the image sensor, as increasing path length of the photon within the CQD film layer provides a higher probability of absorption. According to some aspects, to improve dynamic pixel saturation range, the CQD based image sensor includes a plurality of first pixel electrodes with a first height, and a second plurality of pixel electrodes with a second height which is greater than a first height. The volume of quantum dots above the second pixel electrode is less than the volume of quantum dots above the first pixel electrode, and the smaller volume corresponds to lower quantum efficiency (QE), thus reducing the sensitivity of the second plurality of pixel electrodes and providing an improved dynamic range to combat pixel saturation.

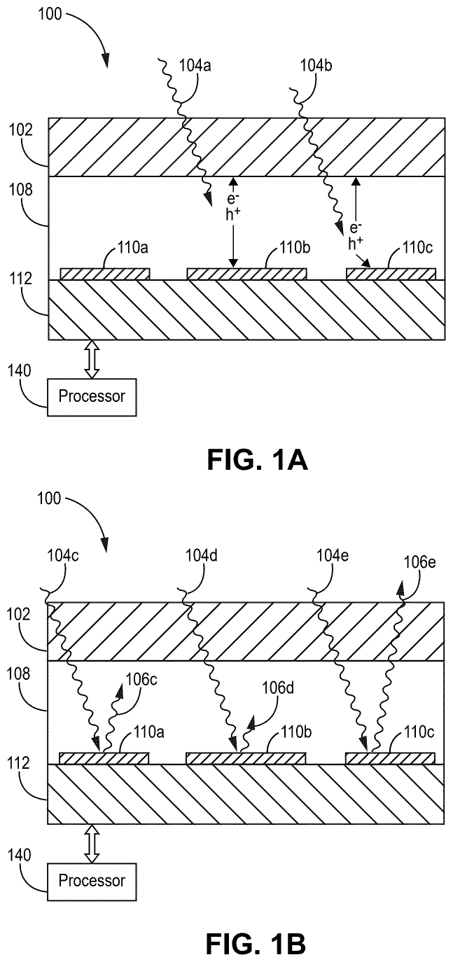

FIG. 1A is cross sectional diagrammatic view of a CQD based image sensor 100, according to some embodiments. The CQD based image sensor 100 includes a top contact 102, a quantum dot film layer 108, a plurality of pixel electrodes 110a, 110b, 110c (collectively, pixel electrodes 110), and a ROIC 112 (readout integrated circuit) in communication with a processor 140. A first photon 104a and a second photon 104b propagate through the top contact 102 and into the quantum dot film layer 108, according to an exemplary embodiment.

As illustrated in FIG. 1A, the photons 104a, 104b (collectively referred to as photons 104) can be absorbed by the quantum dot film layer 108. Absorption of a single photon generates emission of an electron-hole pair (referred to as electron e⁻ and hole h⁺ and/or as majority and minority charge carriers). The top contact 102 is configured to collect the electrons e⁻ and the pixel electrodes 110 are configured to collect the holes h⁺, according to some embodiments. In some embodiments, the top contact 102 is configured to collect the holes h⁺ and the pixel electrodes 110 are configured to collect the electrons e⁻. Each of the plurality of pixel electrodes 110 is in communication with the ROIC 112, which accumulates the photocurrent from each pixel electrode and transfers the resultant signal onto output taps for readout, according to some embodiments. The total photocurrent collected by each of the plurality of pixel electrodes 110a, 110b, 110c is indicative of the magnitude of light incident on the region adjacent each pixel contact.

Absorption of the first photon 104a and the second photon 104b can occur at different locations within the quantum dot film layer 108. For instance, the first photon 104a is absorbed at a position near the top contact 102 and the second photon 104b is absorbed at a position near the pixel electrode 110c. The hole h⁺ generated by the first photon 104a travels further within the quantum dot film layer 108 than the hole h⁺ generated by the second photon 104b. The distance an electron e⁻ or a hole h⁺ need to travel is referred to as a charge carrier transit distance. In general, holes h⁺ have lower mobility through the quantum dot film layer 108 than the electrons e⁻ and are more prone to recombination within the quantum dot film layer 108 prior to collection via the pixel electrodes 110.

FIG. 1B is a cross sectional diagrammatic view of the CQD based image sensor 100 with a third photon 104c, a fourth photon 104d, and a fifth photon 104e propagating through the top contact 102 and into the quantum dot film layer 108, according to an exemplary embodiment. The photons 104c, 104d, 104e are not absorbed by the quantum dot film layer 108 on their first pass through the quantum dot film layer 108. Instead, the photons 104c, 104d, 104e reflect off the pixel electrodes 110, as shown by reflected photons 106c, 106d, 106e. The reflected photons 106c, 106d are absorbed in the quantum dot film layer 108, however, the reflected photon 106e is not absorbed and exits the CQD based image sensor 100. In general, increasing the path length of a photon through the quantum dot film layer 108 increases the probability that the photon will be absorbed in the quantum dot film layer 108.

FIGS. 1A-B illustrate a tradeoff in quantum dot film layer design—an increase in CQD material above the pixel electrode 110 (i.e., the thickness of the quantum dot film layer 108) increases the probability of photon absorption generating an emission of an electron-hole pair. However, an increase in CQD material above the pixel electrode 110 (i.e., the thickness of the quantum dot film layer 108) can increase a charge carrier transit distance, thereby decreasing the probability of the holes h⁺ are collected by the pixel electrode 110.

In some embodiments, the quantum dot film layer 108 is a lead-sulfide (PbS) based layer, including a plurality of colloidal quantum dots embedding in a matrix of ligands. In some embodiments, the colloidal quantum dots are dispersed in a solution and dispensed on a wafer or substrate via spin-coating. In some embodiments, one or more of the ligand matrix, the colloidal quantum dots, and the spin coating can be selected or modified to tune the optical properties of the quantum dot film layer 108, i.e., such that the quantum dot film layer 108 absorbs photons of a desired wavelength range. In some embodiments, the quantum dot film layer 108 has a thickness between 200 nm and 500 nm.

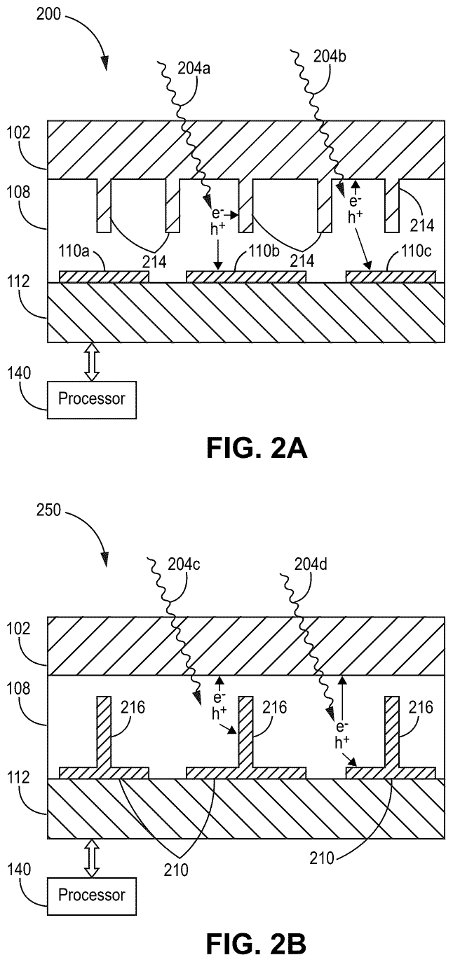

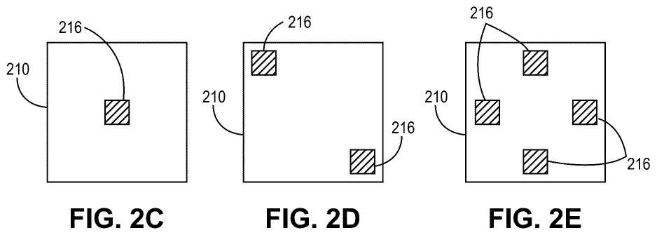

FIG. 2A is a cross sectional diagrammatic view of a CQD based image sensor 200 with a plurality of top contact pillars 214, according to some embodiments. The CQD based image sensor 200 includes a top contact 102, a QD film layer 108, a plurality of pixel electrodes 110, and a ROIC 112. In contrast with the exemplary embodiment shown in FIGS. 1A-B, the CQD based image sensor 200 includes a plurality of top contact pillars 214 extend from the top contact 102 into the quantum dot film layer 108. In some embodiments, the plurality of top contact pillars 214 are formed from the same materials as the top contact 102 and/or may be integrally formed with the top contact 102.

The plurality of top contact pillars 214 are configured to reduce the charge carrier transit distance. For instance, plurality of top contact pillars 214 are configured to reduce the charge carrier transit distance of an electron e⁻generated from photon absorption. A first photon 204a and a second photon 204b propagate into the quantum dot film layer 108. The first photon 204a is absorbed by the quantum dot film layer 108 and the emitted electron e⁻ is collected by the top contact pillar 214, which is closer to the point of absorption than the top contact 102. Electron collection via the top contact 102 is still possible, as for instance, the second photon 204b is absorbed at a location near the top contact 102, and the emitted electron e− is collected by the top contact 102. Electron collection is important, as failure to collect electrons leads to charge imbalances within the quantum dot film layer 108, degrading the efficiency and accuracy of the CQD based image sensor. In some embodiments, the plurality of top contact pillars extend into the quantum dot film layer 108 between 5% and 50% of a total thickness of the quantum dot film layer 108, and in some embodiments, between 10% and 30% of a total thickness of the quantum dot film layer 108. It should be noted that, in some embodiments, the polarity can be reversed such that the plurality of top contact pillars 214 are configured to reduce the charge carrier transit distance of a hole h+ generated from photon absorption.

FIG. 2B is a cross sectional diagrammatic view of a CQD based image sensor 250 with a plurality of pixel electrode pillars 216, according to some embodiments. The CQD based image sensor 250 includes a top contact 102, a QD film layer 108, a plurality of pixel electrodes 110, and a ROIC 112. In contrast with the exemplary embodiment shown in FIGS. 1A-B, the CQD based image sensor 250 includes a plurality of pixel electrode pillars 216 extending from a base portion 210 into the quantum dot film layer 108, according to some embodiments. The plurality of pixel electrode pillars 216 and the base portion 210 are formed of the same material, according to some embodiments.

The plurality of pixel electrode pillars 216 are configured to reduce the charge carrier transit distance for hole h⁺ generated from photon absorption. For example, a third photon 204c is absorbed by the quantum dot film layer 108 and the emitted hole h⁺ is collected by the pixel electrode pillar 216, which is closer to the point of absorption than the base portion 210. Hole collection via the base portion 210 (or the pixel electrode 110 described above) is still possible, as for instance, a fourth photon 204d is absorbed at a location near the base portion 210, and the emitted hole h⁺ is collected by the base portion 210.

In some embodiments, the pixel electrode pillar 216 is positioned on a centerline of the base portion 210. For instance, as shown in FIG. 2C, the base portion 210 may have a rectangular shape (e.g., having a length and width) and the pixel electrode pillar 216 extends along a centerline of a length or a width of the base portion 210. In some embodiments, the pixel electrode pillar 216 is positioned at a centerpoint of the base portion 210. In some embodiments, the pixel electrode pillar 216 is a pillar structure, i.e., the length and width of the pixel electrode pillar 216 are substantially less than the height of the pixel electrode pillar 216. In some embodiments, the base portion 210 includes a plurality of the pixel electrode pillars 216. For example, as shown in FIG. 2D, the base portion 210 may include a first pixel electrode pillar on a first side (e.g., the left side) of the base portion 210 and a second pixel electrode pillar on a second side (e.g., the right side) of the base portion 210. In some embodiments, the base portion 210 may include a pixel electrode pillar on each of the corners of the base portion 210. In some embodiments, such as the exemplary embodiment shown in FIG. 2E, the base portion 210 may include a pixel electrode pillar along each side of the base portion 210. Increasing the number of pixel electrode pillars 216 on the CQD based image sensor 200 may improve QE. In some embodiments, increasing the number of pixel electrode pillars 216 on the CQD based image sensor 200 increases cross-talk between pixel electrodes, as for instance, photons can reflect off of the pixel electrode pillars 216 to other pixel electrodes.

In some embodiments, the pixel electrode pillar 216 has a height between 10% and 75% of a thickness of the quantum dot film layer 108, and in some embodiments, the pixel electrode pillar 216 has a height between 20% and 50% of a thickness of the quantum dot film layer 108. In some embodiments, a height of the pixel electrode pillar 216 is less than a length and/or a width of the base portion 210. The height of the pixel electrode pillar 216 is important, as it reduces a maximum transit distance of a minority charge carrier h⁺, however, an increase in the height will reduce a volume of CQD material present in the quantum dot film layer 108 and/or introduce opportunity for cross talk between pixel electrodes.

In some embodiments, the pixel electrode pillar 216 and the base portion 210 are fabricated via photolithography pattering and deposition of conductive (bottom-contact) electrode material (e.g., gold). For example, the quantum dot film layer 108 can be deposited on a substrate or wafer, and a photolithography process removes (or etches) channels and/or pillar holes into the quantum dot film layer 108. Conductive material is deposited into the channels and/or pillar holes to form the base portion 210 and the pixel electrode pillar 216. The colloidal quantum dots within the quantum dot film layer 108 are spin-coated, and planarize over the substrate and/or other structures of the CQD based image sensor 200.

The CQD based image sensor 200 including pixel electrodes with the pixel electrode pillar 216 and/or with the plurality of top contact pillars 214, which in some embodiments may be used together, reduces a transit distance for photogenerated charge carriers h⁺ and/or e⁻. The pixel electrode pillar 216 and/or the plurality of top contact pillars 214 optimize the inherent tradeoff in quantum dot film layer design (an increase in CQD material above the pixel electrode increases the probability of charge carrier generation, but decreases the probability that the holes h+ and/or electrons e− are collected by the pixel electrode) by reducing photogenerated charge-carrier transit distance without removing substantial CQD material above the pixel electrode.

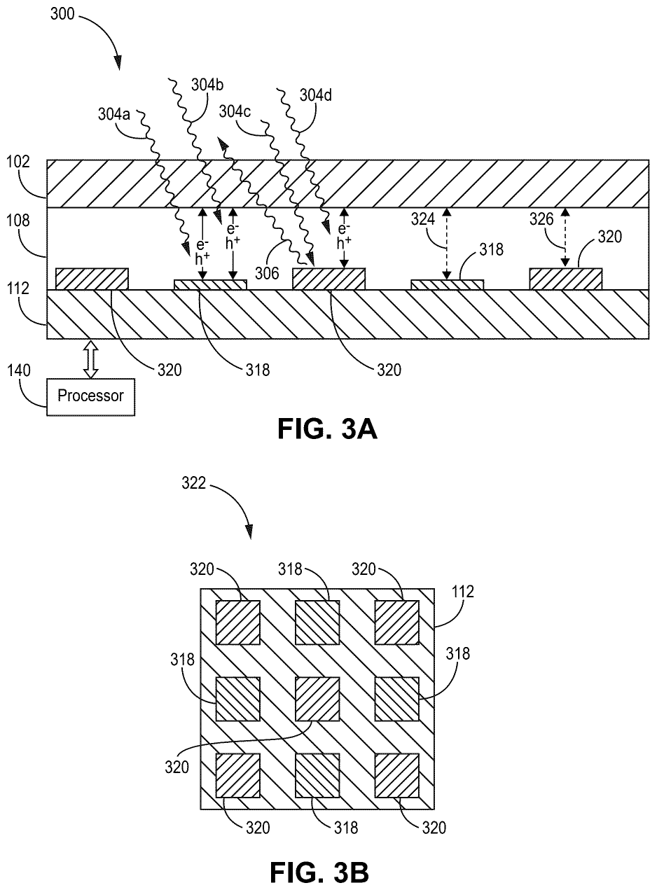

FIG. 3A is a cross sectional diagrammatic view of a CQD based image sensor 300 with a first plurality of pixel electrodes 318 and a second plurality of pixel electrodes 320 having a different height from the first plurality of pixel electrodes 318, according to some embodiments. The first plurality of pixel electrodes 318 and the second plurality of pixel electrodes 320 may include any and/or all features of the pixel electrode 110, the base portion 210, and/or the pixel electrode pillar 216 described above. The first plurality of pixel electrodes 318 and the second plurality of pixel electrodes 320 extend into the quantum dot film layer 108. In some embodiments, the quantum dot film layer 108 includes a first quantum dot film height 324 located above the first pixel electrode 318 and a second quantum dot film height 326 located above the second pixel electrode 320.

In some embodiments, CQD based image sensors can suffer from pixel saturation under bright conditions. For example, the rate of photogenerated charge-carriers increases from high light exposure, resulting in the generated image being oversaturated, or too bright. In some embodiments, to improve dynamic pixel saturation range of the CQD based image sensor 300, two or more heights of pixel electrodes are utilized (e.g., the first plurality of pixel electrodes 318 and the second plurality of pixel electrodes 320). The first quantum dot film height 324 is greater than the second quantum dot film height 326, and therefore, the volume of quantum dots above the first plurality of pixel electrodes 318 is greater than the volume of quantum dots above the second plurality of pixel electrodes 320, which in some embodiments, correlates to a higher quantum efficiency of the first plurality of pixel electrodes 318 relative to the second plurality of pixel electrodes 320. The second plurality of pixel electrodes 320 have a lower quantum efficiency, and therefore, a lower sensitivity to light than the first plurality of pixel electrodes 318.

For instance, exemplary photons 304a, 304b are absorbed by the quantum dot film layer 108 in the volume of quantum dots above the first pixel electrode 318, and the minority charge carriers photogenerated therefrom are collected by the first pixel electrode 318. In contrast, exemplary photons 304c, 304d enter the quantum dot film layer 108 above the second pixel electrode 320, and only the exemplary photon 304d is absorbed by the volume of quantum dots above the second pixel electrode 320. The other exemplary photon 304c reflects off the second pixel electron as a reflected photon 306.

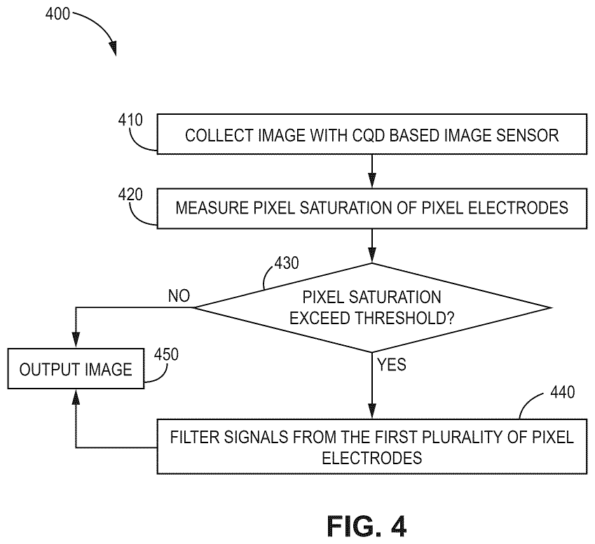

In some embodiments, the height difference between the first plurality of pixel electrodes 318 and the second plurality of pixel electrodes 320 improve the improve dynamic pixel saturation range of the CQD based image sensor 300 by providing higher sensitivity pixel electrodes (e.g., the first plurality of pixel electrodes 318) and lower sensitivity pixel electrodes (e.g., the second plurality of pixel electrodes 320). In some embodiments, image analysis and/or post-processing methods (e.g., as described below in FIG. 4 and/or performed by the processor 140) can be used to detect when a region of the CQD based image sensor 300 has a saturated response. The image from the saturated response region may be filtered or otherwise modified to remove or attenuate the signal(s) from the high sensitivity pixel electrodes. If, for example, no saturated response is detected, the image from the CQD based image sensor 300 may utilize the signal from all pixel electrodes.

FIG. 3B is a top diagrammatic view of a sample region 322 of pixel electrodes of a CQD based image sensor 300 including the first plurality of pixel electrodes 318 and the second plurality of pixel electrodes 320, according to some embodiments. Each of the first plurality of pixel electrodes 318 are separated from one another by the second plurality of pixel electrodes 320, according to some embodiments. For instance, the first plurality of pixel electrodes 318 and the second plurality of pixel electrodes 320 are positioned on a planar surface (e.g., the ROIC 112) and at least one of the second pixel electrodes 320 is positioned between two or more of first pixel electrodes 318. In some embodiments, the number of first plurality of pixel electrodes 318 relative to second plurality of pixel electrodes 320 and/or the distribution thereof may be selected to maximize dynamic pixel saturation range based on a particular application (e.g., expected exposure to light and/or expected wavelength range).

FIG. 4 is a flow chart of a method 400 of improving dynamic range of pixels of a CQD based image sensor, according to some embodiments. In some embodiments, the method 400 is performed by the processor 140. At step 410, the method 400 includes collecting an image with a CQD based image sensor, including the first plurality of pixel electrodes 318 and the second plurality of pixel electrodes 320. The CQD based image sensor may further include any and/or all features of the CQD based image sensor(s) 100, 200, 300 described above. At step 420, the method 400 includes measuring a pixel saturation of pixel electrodes. In some embodiments, measuring pixel saturation includes measuring a sum of minority charge carriers h⁺ collected by the pixel electrodes.

At step 430, the method 400 includes determining whether the measured pixel saturation exceeds a threshold. In some embodiments, a measured pixel saturation for each pixel electrode is compared to an individual threshold. In some embodiments, pixel electrodes are positioned in a plurality of regions, and each region of pixel electrodes is compared to a region threshold to determine a saturation of a region. If, for example, the measured pixel saturation does not exceed a threshold (i.e., equal to or below an acceptable saturation level), the method 400 includes step 450, outputting an image. The output image may include all signals from all pixel electrodes.

If, however, the measured pixel saturation exceeds a threshold (i.e., greater than an acceptable saturation level), the method 400 includes step 440, filtering the signals from the first plurality of pixel electrodes 318. In some embodiments, the signals from the first plurality of pixel electrodes 318 are removed and replaced with a local average of the signals of the second plurality of pixel electrodes 320. In some embodiments, the weight or bias of the signals from the first plurality of pixel electrodes 318 is reduced relative to the signals from the second plurality of pixel electrodes 320. In some embodiments, a correction is made to flatten brightness across the first plurality of pixel electrodes 318 and the second plurality of pixel electrodes 320. Following image processing, at the step 450, an image is output.

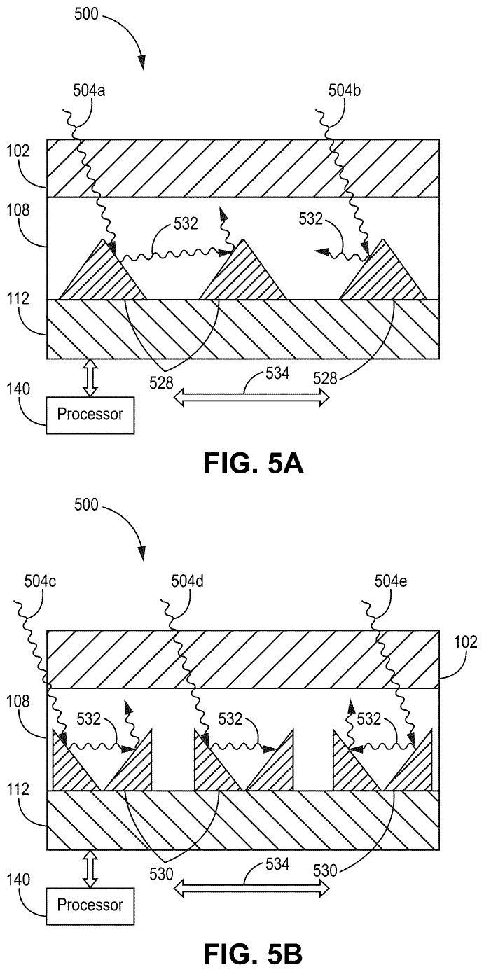

FIG. 5A is a cross sectional diagrammatic view of a CQD based image sensor 500 with a plurality of pyramidal pixel electrodes 528, according to some embodiments. The plurality of pyramidal pixel electrodes 528 include one or more surfaces oriented non-parallel to, and non-orthogonal with, a planar surface (e.g., the ROIC 112) which the plurality of pyramidal pixel electrodes 528 are disposed on. In some embodiments, the one or more surfaces of the plurality of pyramidal pixel electrodes 528 are oriented between 30° and 60° relative to the planar surface.

In some embodiments, the plurality of pyramidal pixel electrodes 528 are configured to reflect photons along a lateral direction 534, substantially parallel with the planar surface. For example, exemplary photons 504a, 504b reflect off the plurality of pyramidal pixel electrodes 528 as reflected photons 532 along the lateral direction 534. The path of light inside the quantum dot film layer 108 is thereby increased, enhancing the probability that incident light is absorbed by the quantum dot film layer 108, thereby boosting quantum efficiency of the CQD based image sensor 500 (e.g., as compared to substantially flat pixel electrodes as shown in FIG. 1B). In some embodiments, the lateral reflection of light may increase cross-talk between adjacent pixel electrodes, as for instance, the reflected photons 532 can travel from one pyramidal pixel electrode to another before absorption.

FIG. 5B is a cross sectional diagrammatic view of a CQD based image sensor 550 with a plurality of inverted pyramidal pixel electrodes 530, according to some embodiments. Each of the plurality of inverted pyramidal pixel electrodes 530 include a recess, cavity, or concave surface configured to reflect incident light toward a center of the inverted pyramidal pixel electrode 530. For instance, exemplary photons 504c, 504d, 504e reflect off each of the plurality of inverted pyramidal pixel electrodes 530, and the reflected photons 532 propagate toward the center of each of the plurality of inverted pyramidal pixel electrodes 530. The plurality of inverted pyramidal pixel electrodes 530 are configured to increase light path length through the quantum dot film layer 108, according to some embodiments. The plurality of inverted pyramidal pixel electrodes 530 are configured to minimize cross-talk between adjacent pixel electrodes, as for instance, the reflected photons 532 may be laterally contained within the recess, cavity, or concave surface region of each of the plurality of inverted pyramidal pixel electrodes 530.

In some embodiments, the plurality of inverted pyramidal pixel electrodes 530 and/or the plurality of pyramidal pixel electrodes 528 include a step-pyramid structure. For instance, the plurality of pyramidal pixel electrodes 528 and/or the plurality of inverted pyramidal pixel electrodes 530 may be fabricated through a photolithography process which removes (or etches) channels and/or cavities into the quantum dot film layer 108.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

### Discussion of Possible Embodiments

The following are non-exclusive descriptions of possible embodiments of the present invention.

In some aspects, the techniques described herein relate to a colloidal quantum dot (CQD) based image sensor, including: a top contact layer; a light absorption layer including a quantum dot film, the quantum dot film including colloidal quantum dots; a readout integrated circuit (ROIC); and a pixel electrode positioned between the quantum dot film and the ROIC, wherein the pixel electrode includes a base portion having a planar surface and a pillar extending from the planar surface toward the top contact layer.

In some aspects, the techniques described herein relate to a CQD based image sensor, wherein the pillar of the pixel electrode extends into the light absorption layer to reduce a transit distance to collect minority carriers.

In some aspects, the techniques described herein relate to a CQD based image sensor, wherein the light absorption layer includes lead sulfide (PbS) quantum dots.

In some aspects, the techniques described herein relate to a CQD based image sensor, wherein the top contact layer includes one or more top contact pillars extending into the light absorption layer, wherein the one or more top contact pillars collects electrons from the light absorption layer to reduce recombination probability.

In some aspects, the techniques described herein relate to a CQD based image sensor, further including a first plurality of the pixel electrodes and a second plurality of the pixel electrodes, wherein the first plurality of the pixel electrodes have a first height and the second plurality of the pixel electrodes have a second height which is greater than the first height.

In some aspects, the techniques described herein relate to a CQD based image sensor, wherein the pillar is positioned on a center point of the pixel electrode.

In some aspects, the techniques described herein relate to a CQD based image sensor, wherein the pixel electrode includes a plurality of the pillars.

In some aspects, the techniques described herein relate to a colloidal quantum dot (CQD) based image sensor system, including: a top contact layer; a light absorption layer including a quantum dot film; a readout integrated circuit (ROIC); a first plurality of pixel electrodes having a first height positioned between the quantum dot film and the ROIC; a second plurality of pixel electrodes having a second height positioned between the quantum dot film and the ROIC, wherein the second height is greater than the first height, wherein the first plurality of pixel electrodes and the second plurality of pixel electrodes collect minority carriers from the light absorption layer and are coupled to the ROIC.

In some aspects, the techniques described herein relate to a CQD based image sensor system, wherein a first volume of the quantum dot film above the first plurality of pixel electrodes is greater than a second volume of the quantum dot film above the second plurality of pixel electrodes.

In some aspects, the techniques described herein relate to a CQD based image sensor system, wherein the first plurality of pixel electrodes and the second plurality of pixel electrodes are positioned on a planar surface, wherein at least one of the second pixel electrodes is positioned between two or more of first pixel electrodes.

In some aspects, the techniques described herein relate to a CQD based image sensor system, further including an image analysis unit in communication with the ROIC, wherein the image analysis unit is configured to measure a first image signal from the first plurality of pixel electrodes, and a second image signal from the second plurality of pixel electrodes and output an image based on the first image signal and the second image signal.

In some aspects, the techniques described herein relate to a CQD based image sensor system, wherein the image analysis unit is configured to measure a saturation of the first plurality of pixel electrodes and the second plurality of pixel electrodes.

In some aspects, the techniques described herein relate to a CQD based image sensor system, wherein if the saturation exceeds a threshold, the image analysis unit increases a weight associated with the second image signal.

In some aspects, the techniques described herein relate to a CQD based image sensor system, wherein the image analysis unit provides a dynamic pixel saturation range by selectively weighting the first image signal and the second image signal based on a measured saturation.

In some aspects, the techniques described herein relate to a CQD based image sensor system, wherein the first plurality of pixel electrodes and the second plurality of pixel electrodes each include a pillar extending into the light absorption layer, wherein the pillar reduces a transit distance to collect minority carriers.

In some aspects, the techniques described herein relate to a colloidal quantum dot (CQD) based image sensor, including: a top contact layer; a light absorption layer including a quantum dot film; a readout integrated circuit (ROIC); a pixel electrode positioned between the quantum dot film and the ROIC on a planar surface, wherein the pixel electrode includes a pyramidal structure.

In some aspects, the techniques described herein relate to a CQD based image sensor, wherein the pyramidal structure includes a surface oriented at an angle of between 10° and 80° relative to the planar surface.

In some aspects, the techniques described herein relate to a CQD based image sensor, wherein the surface of the pyramidal structure is configured to reflect an incident photon laterally within the quantum dot film.

In some aspects, the techniques described herein relate to a CQD based image sensor, wherein the pyramidal structure includes an inverted pyramidal structure.

1. A colloidal quantum dot (CQD) based image sensor, comprising:
a top contact layer;
a light absorption layer including a quantum dot film, the quantum dot film including colloidal quantum dots;
a readout integrated circuit (ROIC); and
a pixel electrode positioned between the quantum dot film and the ROIC, wherein the pixel electrode includes a base portion having a planar surface and a pillar extending from the planar surface toward the top contact layer.

2. The CQD based image sensor of claim 1, wherein the pillar of the pixel electrode extends into the light absorption layer to reduce a transit distance to collect charge carriers.

3. The CQD based image sensor of claim 1, wherein the light absorption layer includes lead sulfide (PbS) quantum dots.

4. The CQD based image sensor of claim 1, wherein the top contact layer includes one or more top contact pillars extending into the light absorption layer, wherein the one or more top contact pillars collects electrons or holes from the light absorption layer to reduce recombination probability.

5. The CQD based image sensor of claim 1, further comprising a first plurality of the pixel electrodes and a second plurality of the pixel electrodes, wherein the first plurality of the pixel electrodes have a first height and the second plurality of the pixel electrodes have a second height which is greater than the first height.

6. The CQD based image sensor of claim 1, wherein the pillar is positioned on a center point of the pixel electrode.

7. The CQD based image sensor of claim 1, wherein the pixel electrode includes a plurality of the pillars.

8. A colloidal quantum dot (CQD) based image sensor system, comprising:
a top contact layer;
a light absorption layer including a quantum dot film;
a readout integrated circuit (ROIC);
a first plurality of pixel electrodes having a first height positioned between the quantum dot film and the ROIC;
a second plurality of pixel electrodes having a second height positioned between the quantum dot film and the ROIC, wherein the second height is greater than the first height,
wherein the first plurality of pixel electrodes and the second plurality of pixel electrodes collect minority carriers from the light absorption layer and are coupled to the ROIC.

9. The CQD based image sensor system of claim 8, wherein a first volume of the quantum dot film above the first plurality of pixel electrodes is greater than a second volume of the quantum dot film above the second plurality of pixel electrodes.

10. The CQD based image sensor system of claim 8, wherein the first plurality of pixel electrodes and the second plurality of pixel electrodes are positioned on a planar surface, wherein at least one of the second pixel electrodes is positioned between two or more of first pixel electrodes.

11. The CQD based image sensor system of claim 8, further comprising an image analysis unit in communication with the ROIC, wherein the image analysis unit is configured to measure a first image signal from the first plurality of pixel electrodes, and a second image signal from the second plurality of pixel electrodes and output an image based on the first image signal and the second image signal.

12. The CQD based image sensor system of claim 11, wherein the image analysis unit is configured to measure a saturation of the first plurality of pixel electrodes and the second plurality of pixel electrodes.

13. The CQD based image sensor system of claim 12, wherein if the saturation exceeds a threshold, the image analysis unit increases a weight associated with the second image signal.

14. The CQD based image sensor system of claim 11, wherein the image analysis unit provides a dynamic pixel saturation range by selectively weighting the first image signal and the second image signal based on a measured saturation.

15. The CQD based image sensor system of claim 8, wherein the first plurality of pixel electrodes and the second plurality of pixel electrodes each include a pillar extending into the light absorption layer, wherein the pillar reduces a transit distance to collect minority or majority carriers.

16. A colloidal quantum dot (CQD) based image sensor, comprising:
a top contact layer;
a light absorption layer including a quantum dot film;
a readout integrated circuit (ROIC);
a pixel electrode positioned between the quantum dot film and the ROIC on a planar surface, wherein the pixel electrode includes a pyramidal structure.

17. The CQD based image sensor of claim 16, wherein the pyramidal structure includes a surface oriented at an angle of between 10° and 80° relative to the planar surface.

18. The CQD based image sensor of claim 17, wherein the surface of the pyramidal structure is configured to reflect an incident photon laterally within the quantum dot film.

19. The CQD based image sensor of claim 16, wherein the pyramidal structure includes an inverted pyramidal structure.
